(19) United States
(12) Patent Application Publication
(10) Pub. No.: US 2014/0166088 A1
(43) Pub. Date: Jun. 19, 2014

(54) PHOTOVOLTAIC DEVICE

(71) Applicant: First Solar, Inc., Tempe, AZ (US)

(72) Inventors: Jongwoo Choi, Latham, NY (US); Hongying Peng, Clifton Park, NY (US); Jinbo Coo, Rexford, NY (US)

(73) Assignee: First Solar, Inc., Tempe, AZ (US)

(21) Appl. No.: 13/719,440

(22) Filed: Dec. 19, 2012

(51) Int. Cl. H01L 31/0264; H01L 31/18

(52) U.S. Cl. CPC H01L 31/0264; H01L 31/1884
USPC 136/255; 136/252; 136/260; 136/265; 438/98

(57) ABSTRACT

An article, such as a photovoltaic device, and methods for making such articles, are provided. For example, one embodiment is an article comprising a plurality of layers comprising an absorber layer and a window stack. The window stack comprises antimony.

### BACKGROUND

The invention generally relates to photovoltaic devices. More particularly, the invention relates to photovoltaic devices that include antimony, and methods of making the photovoltaic devices.

Thin film solar cells or photovoltaic (PV) devices typically include a plurality of semiconductor layers disposed on a transparent substrate, wherein one layer serves as a window layer and a second layer serves as an absorber layer. The window layer allows the penetration of solar radiation to the absorber layer, where the optical energy is converted to usable electrical energy. The window layer further functions to form a heterojunction (p-n junction) in combination with an absorber layer. Cadmium telluride/cadmium sulfide (CdTe/CdS) heterojunction-based photovoltaic cells are one such example of thin film solar cells, where CdS functions as the window layer.

However, thin film solar cells may have low conversion efficiencies. Thus, one of the main focuses in the field of photovoltaic devices is the improvement of conversion efficiency. Absorption of light by the window layer may be one of the phenomena limiting the conversion efficiency of a PV device. Thus, it is desirable to keep the window layer as thin as possible to help reduce optical losses by absorption. However, if the window layer is too thin, a loss in performance is often observed due to low open circuit voltage (V_{OC}) and fill factor (FF).

Thus, there is a need for improved thin film photovoltaic devices configurations, and methods of manufacturing these.

### BRIEF DESCRIPTION OF THE INVENTION

Embodiments of the present invention are provided to meet these and other needs. One embodiment is an article comprising a plurality of layers comprising an absorber layer and a window stack. The window stack comprises antimony.

Another embodiment is a photovoltaic device, comprising a window stack disposed on a support, wherein the window stack comprises a transparent conducting oxide layer (TCO) comprising cadmium tin oxide, a buffer layer comprising zinc tin oxide disposed over the TCO layer, and a window layer comprising cadmium and sulfur disposed over the buffer layer, wherein the window stack comprises a non-uniform distribution of antimony having a maximum concentration point disposed within the buffer layer.

A further embodiment is a method. The method comprises disposing a plurality of layers on a support, wherein the plurality of layers comprises an absorber layer and a window stack, the window stack comprising antimony.

### BRIEF DESCRIPTION OF THE DRAWINGS

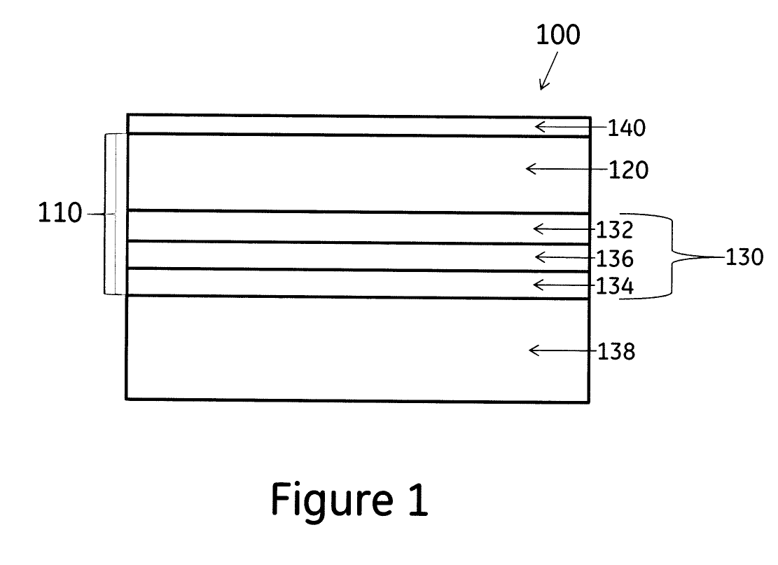

These and other features, aspects, and advantages of the present invention will become better understood when the following detailed description is read with reference to the accompanying drawings in which like characters represent like parts throughout the drawings, wherein FIG. 1 is a schematic cross section of an article in accordance with an embodiment of the present invention.

### DETAILED DESCRIPTION

In the following specification and the claims, the singular forms “a”, “an” and “the” include plural referents unless the context clearly dictates otherwise. As used herein, the term “or” is not meant to be exclusive and refers to at least one of the referenced components being present and includes instances in which a combination of the referenced components may be present, unless the context clearly dictates otherwise.

Approximating language, as used herein throughout the specification and claims, may be applied to modify any quantitative representation that could permissibly vary without resulting in a change in the basic function to which it is related. Accordingly, a value modified by a term or terms, such as “about”, and “substantially” is not to be limited to the precise value specified. In some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise.

The term “transparent” as used herein refers to material that allows an average transmission of at least 70% of incident electromagnetic radiation having a wavelength in a range from about 300 nm to about 850 nm.

In the present disclosure, when a layer is being described as being disposed or positioned “on” another layer or substrate, it is to be understood that the layers can either be directly contacting each other or have one (or more) layer or feature between the layers. Further, the term “on” describes the relative position of the layers to each other and does not necessarily mean “on top of” since the relative position above or below depends upon the orientation of the device to the viewer. Moreover, the use of “top,” “bottom,” “above,” “below,” and variations of these terms is made for convenience, and does not require any particular orientation of the components unless otherwise stated.

As discussed in detail below, some embodiments of the invention are directed to an article, such as a photovoltaic device. An article, illustrated for this example as a photovoltaic device 100, is schematically represented in FIG. 1. Article 100 includes a plurality of layers 110 comprising an absorber layer 120 and a window stack 130. Window stack 130 comprises antimony, meaning that antimony is present within one or more of the layers of window stack 130.

The term “absorber layer” as used herein refers to a semiconducting layer wherein the solar radiation is absorbed. In a photovoltaic device, such as article 100, absorber layer 120 includes a “photo-active” material—a material that absorbs solar radiation and, in response to the absorbed photons, generates electron-hole pairs. In one embodiment, absorber layer 120 includes a p-type semiconductor material. Suitable examples of photo-active materials for use in absorber layer 120 include, without limitation, cadmium telluride (“CdTe”), cadmium zinc telluride, cadmium magnesium telluride, cadmium manganese telluride, cadmium sulfur telluride, cadmium selenium telluride, zinc telluride, copper indium disulfide, copper indium diselenide, copper indium gallium sulfide, copper indium gallium diselenide, copper indium gallium sulfur selenium, copper indium gallium aluminum sulfur selenium, copper zinc tin sulfide, or combinations thereof. Further, these materials may be present in more than one layer, each layer having different type of photo-active material or having combinations of the materials in separate layers. In certain embodiments, the absorber layer 120 includes cadmium telluride. In particular embodiments, the absorber layer 120 includes p-type cadmium telluride. The cadmium telluride, or any of the other absorber materials, may contain dopants and other additives to enhance performance; for example, oxygen may be included in the cadmium telluride.

Window stack 130 comprises transparent material to allow incident light to pass into absorber layer 120. Window stack generally includes a window layer 132 that forms a heterojunction with absorber layer 120. In one embodiment, window layer 132 comprises cadmium and sulfur. Non-limiting exemplary materials for the window layer 132 include cadmium sulfide (CdS), indium III sulfide, zinc sulfide, zinc telluride, zinc selenide, cadmium selenide, oxygenated cadmium sulfide (CdS:O), copper oxide, zinc oxihydrate, or combinations thereof. In certain embodiments, the window layer 132 includes cadmium sulfide. In certain embodiments, the window layer 132 includes oxygenated cadmium sulfide.

Window stack 130 may further comprise a transparent conducting oxide layer (known in the art as a “TCO layer” or simply “TCO”) 134 and, in some embodiments, a comparatively resistant buffer layer 136. The TCO layer 134 and (when present) buffer layer 136 are often referred to in the art as the “front contact” of a photovoltaic device 100. In such a configuration, known as a “superstrate configuration,” stack 130, including front contact components 136 and 134, as applicable, are disposed upon a transparent support 138, and a back contact 140 is disposed over absorber 120. It should be appreciated, however, that the illustration of a superstrate configuration for article 100 is not intended to limit embodiments of the present invention to this configuration.

In some embodiments, the support 138 is transparent over the range of wavelengths for which transmission through the support 138 is desired. In one embodiment, the support 138 may be transparent to visible light having a wavelength in a range from about 400 nm to about 1000 nm. In some embodiments, the support 138 includes a material capable of withstanding heat treatment temperatures greater than about 600° C., such as, for example, silica or borosilicate glass. In some other embodiments, the support 138 includes a material that has a softening temperature lower than 600° C., such as, for example, soda-lime glass or a polyimide. In some embodiments certain other layers may be disposed between window stack 130 and the support 138, such as, for example, an anti-reflective layer or a barrier layer (not shown).

Non-limiting examples of transparent conductive oxides suitable for use in TCO layer 134 include cadmium tin oxide (CTO), indium tin oxide (ITO), fluorine-doped tin oxide (FTO), indium-doped cadmium-oxide, doped zinc oxide ( ) such as aluminum-doped zinc-oxide (AZO), indium-zinc oxide (IZO), and zinc tin oxide, or combinations thereof. Depending on the specific TCO employed and on its sheet resistance, the thickness of the transparent conductive layer 150 may be in a range of from about 50 nm to about 600 nm, in one embodiment.

In some embodiments, the window layer 132 is disposed directly on the TCO layer 134. In alternate embodiments, buffer layer 136 is interposed between the TCO layer 134 and the window layer 120. In some embodiments, the thickness of the buffer layer 136 is up to about 400 nanometers. In certain embodiments, the thickness of buffer layer 136 is at least about 10 nanometers. In particular embodiments, the buffer layer 136 thickness is in a range from about 10 nanometers to about 360 nanometers, and, for example, may be in a range from about 50 nm to about 200 nm. Non-limiting examples of suitable materials for the buffer layer 136 include tin dioxide, zinc tin oxide (also referred to in the art as “ZTO”), zinc-doped tin oxide, zinc oxide, indium oxide, gallium oxide, titanium oxide, or combinations thereof.

As noted above, in embodiments of the present invention, window stack 130 comprises antimony. Although antimony has been investigated previously for its effects on photovoltaic device performance, such investigations generally were concerned with incorporation of antimony within an absorber layer such as CdTe or as part of a back contact. In embodiments of the present invention, antimony is present within window stack 130, such as within buffer layer 136, meaning it is present at a concentration level at least 2 orders of magnitude over what would be expected for devices in which antimony is only incidentally present as an impurity in the front contact or window layer. In the article of the present invention, the antimony may be present as a solute dissolved within one or more materials present within stack 130, or as a constituent of one or more distinct phases that may form upon reaction between antimony and materials within stack 130. In some embodiments, TCO layer 134, buffer layer 136, window layer 120, or some combination of these layers, includes antimony. It is not necessary that antimony be present in all portions of stack 130, or uniformly distributed within stack 130. In fact, in one embodiment the antimony is disposed in a non-uniform distribution within the window stack 130. The distribution of antimony within article 100, in some embodiments, is such that antimony concentration at one or more points within window stack 130 is higher than the average antimony concentration within absorber layer 120. In particular embodiments, buffer layer 136 comprises antimony, and in certain embodiments a non-uniform distribution of antimony within window stack 130 has a maximum concentration within buffer layer 136. Buffer layer 136, in some embodiments comprises at least about 0.1% antimony by weight, and in some embodiments comprises up to about 10% antimony by weight. In particular embodiments, buffer layer 136 comprises from about 1% to about 6% antimony by weight.

As noted earlier, the thickness of the window layer 132 is typically desired to be minimized in a photovoltaic device to achieve high efficiency. With the presence of antimony within window stack 130, the thickness of the window layer 132 (e.g., CdS layer) may be reduced to improve the performance of the present device. Moreover, the present device may achieve a reduction in cost of production because of the use of lower amounts of CdS. Remarkably, the inclusion of antimony within window stack 130 was observed by the present inventors to affect photovoltaic device efficiency differently depending on the thickness of a CdS window layer 132 employed during testing. In devices having a CdS window layer of less than about 90 nanometers, such as, for instance, about 60 nanometers or less, the addition of antimony to window stack 130 appeared to improve all three performance factors (open circuit voltage, short circuit current density, and fill factor) that contribute to device efficiency. In devices having a thicker CdS window layer 130, such as about 90 nanometers, efficiency was improved for devices including antimony within window stack 130, but the improvement in this instance appeared to be only due to improvement in the short circuit current density. Thus, in some embodiments, window layer 132 has a thickness up to about 90 nanometers, and in certain embodiments this thickness is about 60 nanometers or less.

Particular embodiments combine advantages described above. For instance, one embodiment includes a photovoltaic device 100 comprising a window stack 130 disposed on a support 138, wherein the window stack 130 comprises a transparent conducting oxide layer (TCO) 134 comprising cadmium tin oxide, a buffer layer 136 comprising zinc tin oxide disposed over the TCO layer 134, and a window layer 132 comprising cadmium and sulfur disposed over the buffer layer 136. Window stack 130 comprises a non-uniform distribution of antimony; in some embodiments buffer layer 136 comprises antimony, and in particular embodiments, the distribution of antimony within stack 130 has a maximum concentration point disposed within the buffer layer 136.

One embodiment of the present invention includes a method for fabricating device 100. Such a method incudes disposing a plurality of layers 110, for example on a support 138. Plurality of layers 110 includes absorber layer 120 and window stack 130, as these components were described previously. Window stack 130 comprises antimony as noted above.

Techniques suitable for deposition of absorber layer 120 include, for example, close-space sublimation (CSS), vapor transport deposition (VTD), ion-assisted physical vapor deposition (IAPVD), radio frequency or pulsed magnetron sputtering (RFS or PMS), plasma enhanced chemical vapor deposition (PECVD), or electrochemical deposition (ECD).

Window layer 132 may be deposited using a suitable method, such as, for example, close-space sublimation (CSS), vapor transport deposition (VTD), ion-assisted physical vapor deposition (IAPVD), radio frequency or pulsed magnetron sputtering (RFS or PMS), plasma enhanced chemical vapor deposition (PECVD), chemical bath deposition, or electrochemical deposition (ECD). TCO layer 134 and buffer layer 136 may be deposited by methods such as sputtering, chemical vapor deposition, spin coating, spray coating, or dip coating. Such techniques are familiar to those skilled in the art.

Antimony may be included in window stack 130 at the same time as deposition of one or more window stack layers is being deposited, such as by simultaneously sputtering antimony and a layer material from separate sputtering targets, or by using a single sputtering target made of a mixture of antimony with a desired window stack layer material. Other techniques for co-deposition of antimony with materials desirable for use in window layer 132, buffer layer 136, and/or TCO layer 134 may be apparent to those skilled in the art.

Additionally or alternatively, antimony may be included in window stack by depositing a layer rich in antimony, such as elemental antimony or an antimony alloy or compound, over one or more of the layers making up window stack 130. For example, antimony may be included in window stack 130 by disposing an intermediate layer (not shown) comprising antimony on the window layer 132, the TCO layer 134, or the buffer layer 136. This intermediate layer may be applied by any of several physical vapor deposition techniques, for instance, such as sputtering or evaporation. The intermediate, antimony-containing layer is up to about 10 nanometers thick in some embodiments, and up to about 6 nanometers in particular embodiments. The antimony from the intermediate layer may be subsequently distributed within window stack 130 by diffusing antimony from the intermediate layer into at least one of the layers of window stack 130. In some embodiments, this diffusion step is effected incidentally by subsequent processing of the article, such as by deposition of absorber layer 120 using a high temperature deposition process such as close-space sublimation. In other embodiments, a thermal processing step may be applied to effect the desired level of diffusion. In particular embodiments, the time and temperature applied to article 100 during the diffusion step (however effected) is sufficient to create a non-uniform distribution of antimony within window stack 130, such as a distribution having a maximum concentration within window stack 130 occurring within buffer layer 136.

### EXAMPLE

The following example is provided to further illustrate embodiments of the present invention and is not presented as a limitation of the inventive scope.

Photovoltaic devices were fabricated by sputtering oxygenated cadmium sulfide (CdS:O) over glass supports previously coated with a cadmium tin oxide TCO layer and a zinc tin oxide buffer layer. The devices had various respective window layer thicknesses, ranging from 30 nanometers to 60 nanometers nominal thickness. For each window layer thickness, control devices were fabricated with no antimony included in the processing, while experimental devices were further coated with a nominally 5 nanometer thick layer of elemental antimony deposited by DC sputtering. Absorber layers of CdTe were deposited at temperatures exceeding 550 degrees Celsius, and a passivation treatment using cadmium chloride was used, which included a thermal treatment at nominally 400 degrees Celsius. A SIMS chemical profile through the cross section of such an experimental device showed a non-uniform distribution of antimony having a maximum point located within the buffer layer. For each window layer thickness class, devices including antimony had statistically significant increases in efficiency compared to the control devices. Moreover, the devices showed increases in open circuit potential, short circuit current density, and fill factor.

While only certain features of the invention have been illustrated and described herein, many modifications and changes will occur to those skilled in the art. It is, therefore, to be understood that the appended claims are intended to cover all such modifications and changes as fall within the true spirit of the invention.

1. An article comprising:
a plurality of layers comprising an absorber layer and a window stack, the window stack comprising antimony.

2. The article of claim 1, wherein the window stack further comprises a window layer, a transparent conducting oxide (TCO) layer, and a buffer layer, wherein the window layer, the TCO layer, the buffer layer, or a combination of these, comprises antimony.

3. The article of claim 2, wherein the antimony is disposed in a non-uniform distribution within the window stack.

4. The article of claim 3, wherein the non-uniform distribution of antimony within the window stack has a maximum concentration within the buffer layer.

5. The article of claim 1, wherein the absorber layer comprises a chalcogenide comprising cadmium and tellurium.

6. The article of claim 2, wherein the window layer comprises cadmium and sulfur.

7. The article of claim 6, wherein the window layer comprises cadmium sulfide.

8. The article of claim 7 wherein the window layer has a thickness of up to about 90 nanometers.

9. The article of claim 7 wherein the window layer has a thickness of up to about 60 nanometers.

10. The article of claim 2, wherein the TCO layer comprises indium tin oxide, fluorine-doped tin oxide, or cadmium tin oxide.

11. The article of claim 2, wherein the buffer layer comprises zinc oxide, zinc tin oxide, or titanium oxide.

12. A photovoltaic device, comprising:
a window stack disposed on a support, wherein the window stack comprises
a transparent conducting oxide layer (TCO) comprising cadmium tin oxide,
a buffer layer comprising zinc tin oxide disposed over the TCO layer, and
a window layer comprising cadmium and sulfur disposed over the buffer layer,
wherein the window stack comprises a non-uniform distribution of antimony having a maximum concentration point disposed within the buffer layer.

13. A method comprising:
disposing a plurality of layers on a support, wherein the plurality of layers comprises an absorber layer and a window stack, the window stack comprising antimony.

14. The method of claim 13, wherein the disposing step comprises disposing a window stack comprising a window layer, a transparent conducting oxide (TCO) layer, and a buffer layer, wherein the window layer, the TCO layer, the buffer layer, or a combination of these, comprises antimony.

15. The method of claim 14, wherein window stack comprises a window layer, a transparent conducting oxide (TCO) layer, and a buffer layer, and wherein the disposing step comprises disposing an intermediate layer comprising antimony on the window layer, the TCO layer, or the buffer layer.

16. The method of claim 15, wherein the intermediate layer has a thickness of up to about 10 nanometers.

17. The method of claim 15, further comprising diffusing antimony from the intermediate layer into at least one of the layers of the window stack.

18. The method of claim 13, wherein a maximum value of antimony concentration within the window stack occurs within a buffer layer of the window stack.
